(19) United States
(12) Patent Application Publication
(10) Pub. No.: US 2023/0335972 A1
(43) Pub. Date: Oct. 19, 2023

(54) SEMICONDUCTOR LASER AND SEMICONDUCTOR LASER DEVICE

(71) Applicant: SONY GROUP CORPORATION, TOKYO (JP)

(72) Inventors: YUTA ISOZAKI, KUMAMOTO (JP); HIDEKAZU KAWANISHI, KUMAMOTO (JP); YUICHIRO KIKUCHI, KUMAMOTO (JP); YUKIO HOSHINA, KUMAMOTO (JP); HIDEKI WATANABE, KUMAMOTO (JP)

(21) Appl. No.: 18/042,617

(22) PCT Filed: Aug. 6, 2021
(86) PCT No.: PCT/JP2021/029245

§ 371 Date: Feb. 23, 2023

(30) Foreign Application Priority Data
Sep. 7, 2020 (JP) 2020-150096

(51) Int. Cl. H01S 5/024; H01S 5/22

(52) U.S. Cl. CPC H01S 5/02469; H01S 5/22

(57) ABSTRACT

A semiconductor laser according to one embodiment of the present disclosure includes: a first semiconductor layer; an active layer; and a second semiconductor layer stacked on the first semiconductor layer with the active layer interposed therebetween, and having a strip-shaped ridge, and a high-resistance region at a foot of the ridge. The semiconductor laser further includes an insulating layer formed so as to be in contact with both side surfaces of the ridge in a width direction of the ridge and to expose at least a portion of the high-resistance region, and an electrode layer in contact with an upper surface of the ridge, and in contact with all or a part of an exposed portion of the high-resistance region which is not covered with the insulating layer.

### TECHNICAL FIELD

The present disclosure relates to a semiconductor laser and a semiconductor laser device.

### BACKGROUND ART

An edge-emitting semiconductor laser is disclosed, for example, in Patent Literature 1 below.

### CITATION LIST

### Patent Literature

Patent Literature 1: Japanese Unexamined Patent Application Publication No. 2005-311309

### SUMMARY OF THE INVENTION

An edge-emitting semiconductor laser is demanded to have an improved heat dissipation property in order to suppress a decrease in output due to a heat generation. Therefore, it is desirable to provide a semiconductor laser with high heat dissipation and a semiconductor laser device having such a semiconductor laser.

A semiconductor laser according to one embodiment of the present disclosure includes: a first semiconductor layer; an active layer; and a second semiconductor layer stacked on the first semiconductor layer with the active layer interposed therebetween, and having a strip-shaped ridge, and a high-resistance region at a foot of the ridge. The semiconductor laser further includes an insulating layer formed so as to be in contact with both side surfaces of the ridge in a width direction of the ridge and to expose at least a portion of the high-resistance region, and an electrode layer electrically coupled to an upper surface of the ridge, and in contact with all or a part of an exposed portion of the high-resistance region which is not covered with the insulating layer.

A semiconductor laser device according to one embodiment of the present disclosure includes: a semiconductor laser; and a connection pad electrically coupled to the semiconductor laser. The semiconductor laser includes: a first semiconductor layer; an active layer; and a second semiconductor layer stacked on the first semiconductor layer with the active layer interposed therebetween, and having a strip-shaped ridge, and a high-resistance region at a foot of the ridge. The semiconductor laser further includes an insulating layer formed so as to be in contact with both side surfaces of the ridge in a width direction of the ridge and to expose at least a portion of the high-resistance region, and an electrode layer electrically coupled to an upper surface of the ridge and the connection pad, and in contact with all or a part of an exposed portion of the high-resistance region which is not covered with the insulating layer.

In the semiconductor laser and the semiconductor laser device according to one embodiment of the present disclosure, the insulating layer is formed in contact with the both side surfaces of the ridge, and the electrode layer is formed that is electrically coupled to the upper surface of the ridge, and in contact with the exposed portion of the high-resistance region which is not covered with the insulating layer. As a result, a heat generated in the active layer is transferred to the electrode layer through the upper surface of the ridge and the high-resistance region, making it possible to improve a heat dissipation as compared with a case where an insulating layer is provided to cover a side surface and a foot of the ridge. In addition, because it is difficult for a current to flow in the high-resistance region, it is possible to improve heat dissipation while preventing a current path from being generated at a location other than the ridge.

### BRIEF DESCRIPTION OF THE DRAWINGS

FIG. 1 is a diagram illustrating a perspective configuration example of a semiconductor laser according to a first embodiment of the present disclosure.

FIG. 2 is a diagram illustrating a cross-sectional configuration example of the semiconductor laser of FIG. 1 taken along line A-A.

FIG. 3 is a diagram illustrating a cross-sectional configuration example of the semiconductor laser of FIG. 1 taken along line B-B.

FIG. 4A is a diagram illustrating an example of a method of manufacturing the semiconductor laser of FIG. 1.

FIG. 4B is a diagram illustrating a cross-sectional configuration example of FIG. 4A taken along the line A-A.

FIG. 4C is a diagram illustrating a cross-sectional configuration example of FIG. 4A taken along line B-B.

FIG. 5A is a diagram illustrating an example of a manufacturing process following FIG. 4A.

FIG. 5B is a diagram illustrating a cross-sectional configuration example of FIG. 5A taken along line A-A.

FIG. 5C is a diagram illustrating a cross-sectional configuration example of FIG. 5A taken along line B-B.

FIG. 6A is a diagram illustrating an example of a manufacturing process following FIG. 5A.

FIG. 6B is a diagram illustrating a cross-sectional configuration example of FIG. 6A taken along line A-A.

FIG. 6C is a diagram illustrating a cross-sectional configuration example of FIG. 6A taken along line B-B.

FIG. 7A is a diagram illustrating an example of a manufacturing process following FIG. 6A.

FIG. 7B is a diagram illustrating a cross-sectional configuration example of FIG. 7A taken along line A-A.

FIG. 7C is a diagram illustrating a cross-sectional configuration example of FIG. 7A taken along line B-B.

FIG. 8 is a diagram illustrating a modification example of the semiconductor laser of FIG. 1.

FIG. 9 is a diagram illustrating a cross-sectional configuration example of the semiconductor laser of FIG. 8 taken along line A-A.

FIG. 10 is a diagram illustrating a cross-sectional configuration example of the semiconductor laser of FIG. 8 taken along line B-B.

FIG. 11 is a diagram illustrating a modification example of the semiconductor laser of FIG. 1.

FIG. 12 is a diagram illustrating a cross-sectional configuration example of the semiconductor laser of FIG. 11 taken along line A-A.

FIG. 13 is a diagram illustrating a cross-sectional configuration example of the semiconductor laser of FIG. 11 taken along line B-B.

FIG. 14 is a diagram illustrating a modification example of the semiconductor laser of FIG. 1.

FIG. 15 is a diagram illustrating a cross-sectional configuration example of the semiconductor laser of FIG. 14 taken along line A-A.

FIG. 16 is a diagram illustrating a cross-sectional configuration example of the semiconductor laser of FIG. 14 taken along line B-B.

FIG. 17 is a diagram illustrating a modification example of the semiconductor laser of FIG. 2.

FIG. 18 is a diagram illustrating a modification example of the semiconductor laser of FIG. 9.

FIG. 19 is a diagram illustrating a cross-sectional configuration example of a semiconductor laser device according to a second embodiment of the present disclosure.

### MODES FOR CARRYING OUT THE INVENTION

Hereinafter, embodiments of the present disclosure are described in detail with reference to drawings. The following description is a specific example of the present disclosure, and the present disclosure is not limited to the following embodiments. In addition, the present disclosure is not limited to the arrangement, dimensions, dimensional ratios, etc., of each component illustrated in each drawing. The description will be made in the following order.
1. First Embodiment (a semiconductor laser)
2. Modification Examples (a semiconductor laser)
3. Second Embodiment (a semiconductor laser device)

### 1. First Embodiment

[Configuration]

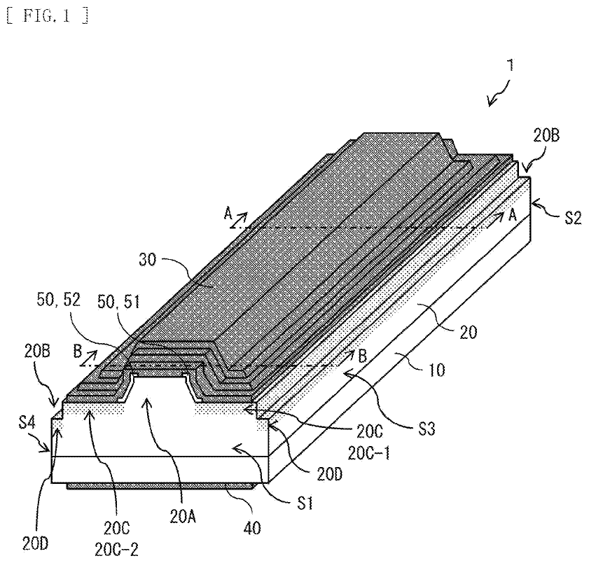

A semiconductor laser 1 according to a first embodiment of the present disclosure will be described. FIG. 1 illustrates a perspective configuration example of the semiconductor laser 1 according to the present embodiment.

The semiconductor laser 1 has a structure in which a semiconductor layer 20, which will be described later, is sandwiched between a pair of resonator end faces S1 and S2 from a resonator direction. In other words, the pair of resonator end faces S1 and S2 are opposed to each other via a ridge 20A in a direction parallel to an extending direction of the ridge 20A, which will be described later. The resonator end face S1 is a front end face from which laser light is emitted to the outside, and the resonator end face S2 is a rear end face opposed to the resonator end face S1. Therefore, the semiconductor laser 1 is a kind of so-called edge emitting semiconductor laser.

The semiconductor laser 1 (a semiconductor layer 20) includes the resonator end faces S1 and S2 facing each other in the resonator direction, and the convex ridge 20A sandwiched between the resonator end faces S1 and S2. The ridge 20A has a strip-like shape extending in the resonator direction. The ridge 20A is formed, for example, by etching away from a surface of a contact layer 26, which will be described later, to the middle of a first upper clad layer 25, which will be described later. That is, a part of the first upper clad layer 25 is exposed on both sides of the ridge 20A.

The width of the ridge 20A (the length in the direction orthogonal to the resonator direction) is, for example, 0.5 μm or more and 100 μm or less, and is, for example, 40 μm. The length of the ridge 20A in the resonator direction is, for example, 50 μm or more and 3000 μm or less, for example, 1200 μm. Hereinafter, the width refers to the length in the direction intersecting the resonator direction. In addition, the direction intersecting with the resonator direction is referred to as the “width direction”.

One end surface of the ridge 20A is exposed at the resonator end face S1, and the other end surface of the ridge 20A is exposed at the resonator end face S2. The resonator end faces S1 and S2 are faces formed by cleavage. The resonator end faces S1 and S2 function as resonator mirrors, and the ridge 20A functions as an optical waveguide. The resonator end face S1 may be provided with, for example, an antireflection film configured so that the reflectance at the resonator end face S1 is approximately 15%. The resonator end face S2 may be provided with, for example, a multilayer reflective film configured so that the reflectance at the resonator end face S2 is approximately 95%. The semiconductor laser 1 (the semiconductor layer 20) further has a pair of side surfaces S3 and S4 facing each other in the width direction. The pair of side surfaces S3 and S4 are desirably surfaces formed by dicing, cleavage, or splitting.

The semiconductor laser 1 includes an insulating layer 50 in contact with both side surfaces in the width direction of the ridge 20A. The insulating layer 50 protects the ridge 20A and defines a region where a current is injected into the semiconductor layer 20 (that is, a region where the ridge 20A and the upper electrode layer 30 are in contact with each other). The insulating layer 50 is further configured such that at least a portion of the high-resistance region 20C (20C-1, 20C-2), which will be described later, is exposed, and to be in contact with at least a portion of the high-resistance region 20C (20C-1, 20C-2).

The insulating layer 50 has, for example, an insulating layer 51 and an insulating layer 52 facing each other with the upper surface of the ridge 20A therebetween and extending in a direction parallel to the extending direction of the ridge 20A. The insulating layer 51 is formed from one side surface (a first side surface) of the ridge 20A to the edge of a high-resistance region 20C-1, which will be described later. That is, in a case where there is a region having a lower resistance than the high-resistance region 20C-1 in the first upper clad layer 25 between one side surface (first side surface) of the ridge 20A and the high-resistance region 20C-1, the insulating layer is formed to cover such a region. The insulating layer 52 is formed from the other side surface (second side surface) of the ridge 20A to the edge of the high-resistance region 20C-2, which will be described later. That is, in a case where there is a region having a lower resistance than the high-resistance region 20C-2 in the first upper clad layer 25 between the other side surface (second side surface) of the ridge 20A and the high-resistance region 20C-2, the insulating layer 52 is formed to cover such a region. The insulating layers 51 and 52 are configured by, for example, SiO₂ layers or SiN layers having a thickness of 10 nm to 500 nm.

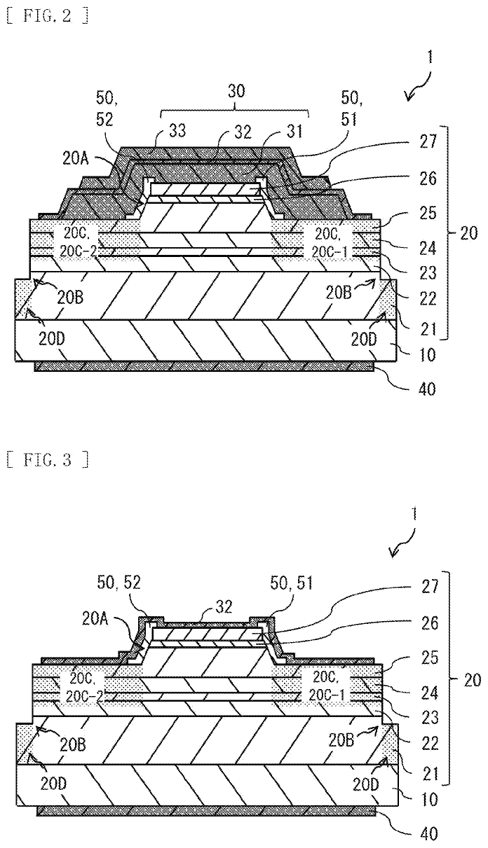

FIG. 2 illustrates an example of a cross-sectional configuration of the semiconductor laser 1 of FIG. 1 taken along line A-A. FIG. 3 illustrates a cross-sectional configuration example of the semiconductor laser 1 of FIG. 1 taken along the line B-B. FIGS. 2 and 3 illustrate an example of a lateral cross-sectional configuration of the semiconductor laser 1. FIG. 3 illustrates an example of a cross-sectional configuration of the semiconductor laser 1 in the vicinity of the resonator end face S1).

The semiconductor laser 1 has a semiconductor layer 20 on a substrate 10. The semiconductor layer 20 includes, for example, a lower clad layer 21, a lower guide layer 22, an active layer 23, an upper guide layer 24, a first upper clad layer 25, a contact layer 26, and a second upper clad layer 27 in this order from the substrate 10 side. The upper guide layer 24, the first upper clad layer 25, the contact layer 26, and the second upper clad layer 27 are stacked on the lower guide layer 22 with active layer 23 interposed therebetween. The semiconductor layer 20 may be further provided with a layer (for example, a buffer layer) other than the layers described above. In addition, in the semiconductor layer 20, for example, the second upper clad layer 27 may be omitted.

The substrate 10 is, for example, a crystal growth substrate used for epitaxial crystal growth of the active layer 23 and the like. The substrate 10, the lower clad layer 21, the lower guide layer 22, the active layer 23, the upper guide layer 24, the first upper clad layer 25, and the contact layer 26 include, for example, a gallium nitride-based semiconductor. The substrate 10 is, for example, a GaN substrate. The lower clad layer 21, the lower guide layer 22, the active layer 23, the upper guide layer 24, the first upper clad layer 25, and the contact layer 26 include, for example, GaN, AlGaN, AlInN, GaInN, AlGaInN, and the like.

The lower clad layer 21 and the lower guide layer 22 include, for example, silicon (Si) as an n-type impurity. That is, the lower clad layer 21 and the lower guide layer 22 are n-type semiconductor layers. The upper guide layer 24, the first upper clad layer 25, and the contact layer 26 include, for example, magnesium (Mg), zinc (Zn), etc., as p-type impurities. That is, the upper guide layer 24, the first upper clad layer 25, and the contact layer 26 are p-type semiconductor layers. The active layer 23 has, for example, a quantum well structure. Types of quantum well structures include, for example, a single quantum well structure (QW structure) and a multiple quantum well structure (MQW structure). The quantum well structure has a structure in which well layers and barrier layers are alternately stacked. Examples of combinations of well layers and barrier layers include (In_{y}Ga_{(1-y)}N, GaN), (In_{y}Ga_{(1-y)}N, In_{z}Ga_{(1-z)} N) [where y>z], (In_{y}Ga_{(1-y)}N, AlGaN) and the like.

The second upper clad layer 27 is formed in contact with the top of the ridge 20A (specifically, the contact layer 26). The second upper clad layer 27 includes, for example, a transparent conductive material. Examples of transparent conductive materials include ITO (Indium Tin Oxide), ITiO (Indium Titanium Oxide), AZO (Al₂O₃—ZnO), and IGZO (InGaZnOx). These transparent conductive materials have a higher conductivity than the semiconductor layers forming the ridge 20A and a higher refractive index than the semiconductor layers forming the ridge 20A. Therefore, by using a transparent conductive material for the second upper clad layer 27 and forming the ridge 20A low, it is possible to reduce a driving voltage of the semiconductor laser 1 and improve an optical confinement in the stacking direction.

The semiconductor layer 20 has a high-resistance region 20C at a foot of the ridge 20A, as illustrated in FIGS. 1 to 3, for example. The foot of the ridge 20A is a region of the surface of the semiconductor layer 20 on the side of the ridge 20A (hereinafter referred to as “upper surface of the semiconductor layer 20”.) excluding the ridge 20A. The high-resistance region 20C is formed at least in the first upper clad layer 25 of the semiconductor layer 20. The high-resistance region 20C is a region formed by increasing a resistance of at least a portion of the first upper clad layer 25 of the semiconductor layer 20 by, for example, ion implantation into at least the first upper clad layer 25 of the semiconductor layer 20.

As illustrated in FIGS. 2 and 3, for example, the high-resistance region 20C may be formed to extend from the surface of the region corresponding to the foot of the ridge 20A in the first upper clad layer 25 to the depth reaching the active layer 23. It should be noted that FIGS. 2 and 3 illustrates an example in which the high-resistance region 20C is formed in the first upper clad layer 25 from the surface of the region corresponding to the foot of the ridge 20A to the depth reaching the lower guide layer 22.

The high-resistance region 20C has, for example, a high-resistance region 20C-1 formed on one side surface (first side surface) of the ridge 20A and a high-resistance region 20C-2 formed on the other side surface (second side surface) of the ridge 20A. The high-resistance regions 20C-1 and 20C-2 extend in the resonator direction of at the foot of the ridge 20A. The high-resistance region 20C-1 is formed, for example, from a portion of the semiconductor layer 20 in contact with the side surface of the ridge 20A to the side surface S3. Note that the high-resistance region 20C-1 may be formed, for example, from a portion of the semiconductor layer 20 which is away from the side surface of the ridge 20A by a predetermined distance to the side surface S3. The high-resistance region 20C-2 is formed, for example, from a portion of the semiconductor layer 20 in contact with the side surface of the ridge 20A to the side surface S4. The high-resistance region 20C-2 may be formed, for example, from a portion of the semiconductor layer 20 which is away from the side surface of the ridge 20A by a predetermined distance to the side surface S4. For example, the high-resistance region 20C-1 may be exposed (or formed) on the side surface S3 of the semiconductor layer 20 on one side surface (first side surface) of the ridge 20A. For example, the high-resistance region 20C-2 may be exposed (or formed) on the side surface S4 of the semiconductor layer 20 on the other side surface (second side surface) side of the ridge 20A. The high-resistance regions 20C-1 and 20C-2 may also be exposed (or formed) at, for example, portions of the resonator end faces S1 and S2 corresponding to the foot of the ridge 20A.

Boron (B), nitrogen (N), proton (H), or the like, for example, is used when the high-resistance region 20C is formed by ion implantation. In a case where boron (B) is used in the ion implantation, an implantation energy is set in the range of 40 keV to 160 keV, and the dose is set in the range of 2×10¹³ cm⁻² to 2×10¹⁵ cm⁻². In order to make the ion implantation concentration uniform in the depth direction, for example, ion implantation may be performed multiple times with different implantation energies.

A stepped portion 20B may be provided on the side surfaces S3 and S4, as illustrated in FIGS. 1 to 3, for example. The stepped portion 20B is formed, for example, by etching the semiconductor layer 20 from the first upper clad layer 25 side to at least a depth penetrating the active layer 23. A high-resistance region 20D may be formed in the stepped portion 20B, as illustrated in FIGS. 1 to 3, for example. The high-resistance region 20D is a region formed by increasing the resistance of a portion of the stepped portion 20B by ion implantation into the stepped portion 20B, for example. A method of forming the high-resistance region 20D by ion implantation is similar to the method of forming the high-resistance region 20C by ion implantation.

The semiconductor laser 1 further includes an upper electrode layer 30 on the upper surface side of the semiconductor layer 20 and a lower electrode layer 40 on the rear surface side of the semiconductor layer 20.

The upper electrode layer 30 is formed on the ridge 20A and electrically coupled to the upper surface of the ridge 20A. The upper electrode layer 30 is formed on the ridge 20A via a second upper clad layer 27 formed in contact with the upper surface of the ridge 20A (specifically, the contact layer 26), and is electrically coupled to the contact layer 26. The upper electrode layer 30 is also formed on the foot of the ridge 20A and is in contact with an exposed portion of the high-resistance region 20C which is not covered with the insulating layer 50. In other words, the upper electrode layer 30 is in direct contact with the foot of the ridge 20A (the high-resistance region 20C).

The upper electrode layer 30 has, for example, a pad metal 31, a barrier metal 32, and a bonding metal 33 in this order from the ridge 20A side.

The pad metal 31 is a metal layer for injecting an externally supplied current into the ridge 20A. The pad metal 31 has, for example, a structure in which a titanium (Ti) layer, a platinum (Pt) layer, and a gold (Au) layer are stacked in this order from the side closer to the ridge 20A. The thickness of the Ti layer is, for example, 2 nm or more and 100 nm or less. The thickness of the Pt layer is, for example, 10 nm or more and 300 nm or less. The thickness of the Au layer is, for example, 10 nm or more and 3000 nm or less. The pad metal 31 may be electrically coupled to the upper surface of the ridge 20A, and its layer structure is not limited to the above structure.

The pad metal 31 is in contact with the second upper clad layer 27 and is electrically coupled to the upper surface of the ridge 20A (specifically, the contact layer 26) via the second upper clad layer 27. The pad metal 31 is formed between the resonator end face S1 and the resonator end face S2. Specifically, the pad metal 31 is formed in a region between the resonator end face S1 and the resonator end face S2 and separated from the resonator end face S1 and the resonator end face S2 by a predetermined gap. Hereinafter, a region between the resonator end faces S1 and S2 and in which the pad metal 31 is not formed will be referred to as a first end region.

The width of the pad metal 31 is wider than the width of the second upper clad layer 27. For example, in a case where the chip width is 150 μm, the width is 5 μm or more and 140 μm or less. The pad metal 31 is in contact with the insulating layers 51 and 52, and also in contact with exposed portions of the high-resistance regions 20C-1 and 20C-2 which are not covered with the insulating layers 51 and 52. The pad metal 31 is formed between the side surface S3 and the side surface S4. Specifically, the pad metal 31 is formed in a region between the side surface S3 and the side surface S4 and separated from the side surfaces S3 and S4 by a predetermined gap. Hereinafter, a region between the side surfaces S3 and S4 and in which the pad metal 31 is not formed will be referred to as a second end region. Because the pad metal 31 is sufficiently separated from the resonator end faces S1 and S2 in this manner, the pad metal 31 is prevented from protruding from the resonator end faces S1 and S2 or touching the resonator end faces S1 and S2. Further, because the pad metal 31 is sufficiently spaced from the side surfaces S3 and S4, the pad metal 31 is prevented from protruding from the side surfaces S3 and S4 and from touching the side surfaces S3 and S4. Moreover, as compared with a case where the pad metal 31 is also formed in the first end region and the second end region, the stress applied to the ridge 20A through the pad metal 31 is reduced.

The barrier metal 32 is a metal layer for suppressing diffusion of a component of solder (for example, tin (Sn)) from the bonding metal 33 side to the pad metal 31 side. If the solder component (for example, Sn) continues to diffuse into the pad metal 31, the edges of the pad metal 31 may suddenly deteriorate. Such sudden deterioration of the pad metal 31 impairs the long-term reliability of the semiconductor laser 1. Therefore, the barrier metal 32 is a layer for ensuring long-term reliability of the semiconductor laser 1.

The barrier metal 32 has, for example, a structure in which a Ti layer and a Pt layer are stacked in this order from the side closer to the ridge 20A, and includes a metal layer that does not have wettability to a Sn-based solder. The thickness of the Ti layer is, for example, 2 nm or more and 500 nm or less. The thickness of the Pt layer is, for example, 2 nm or more and 100 nm or less. The pad metal 31 may have a structure capable of suppressing the diffusion of solder component (for example, Sn) from the bonding metal 33 side to the pad metal 31 side, and its layer configuration is not limited to the above configuration. The outermost surface of the barrier metal 32 (the surface on the bonding metal 33 side) preferably includes a metal (for example, Ti, Pt, aluminum (Al) or nickel (Ni)) that does not have wettability to the Sn-based solder.

The barrier metal 32 is formed to cover the pad metal 31. Specifically, the barrier metal 32 is formed to cover both ends of the pad metal 31 in the resonator direction, both ends of the pad metal 31 in the width direction, and at least a region in the vicinity of the end of the pad metal 31 out of the formation surface of the pad metal 31. This prevents direct contact between the pad metal 31 and the bonding metal 33. The barrier metal 32 is further disposed sufficiently away from side surfaces S3 and S4. This prevents the barrier metal 32 from protruding from the side surfaces S3 and S4 and from touching the side surfaces S3 and S4.

The bonding metal 33 is, for example, a metal layer with which solder contacts. The bonding metal 33 has, for example, a structure in which a Ti layer and an Au layer are stacked in this order from the side closer to the ridge 20A. The thickness of the Ti layer is, for example, 2 nm or more and 500 nm or less. The thickness of the Au layer is, for example, 10 nm or more and 1000 nm or less. The outermost surface of the bonding metal 33 preferably includes a metal (for example, Au, silver (Ag) or palladium (Pd)) having wettability to the Sn-based solder.

The bonding metal 33 is formed in contact with the surface of the barrier metal 32. The bonding metal 33 is formed between the resonator end face S1 and the resonator end face S2. Specifically, the bonding metal 33 is formed in a region between the resonator end face S1 and the resonator end face S2 and separated from the resonator end faces S1 and S2 by a predetermined gap. Because the bonding metal 33 is sufficiently separated from the resonator end faces S1 and S2 in this manner, the bonding metal 33 is prevented from protruding from the resonator end faces S1 and S2 or touching the resonator end faces S1 and S2. Moreover, the bonding metal 33 is formed between the side surfaces S3 and S4. Specifically, the bonding metal 33 is formed in a region between the side surface S3 and the side surface S4 and separated from the side surfaces S3 and S4 by a predetermined gap. By disposing the bonding metal 33 sufficiently away from the side surfaces S3 and S4 in this manner, the bonding metal 33 is prevented from protruding from the side surfaces S3 and S4 and from touching the side surfaces S3 and S4.

The lower electrode layer 40 is formed, for example, in contact with the back surface of the substrate 10. The lower electrode layer 40 has a structure in which at least two layers selected from, for example, a Ti layer, an Al layer, a vanadium (V) layer, a Pt layer, and an Au layer are stacked. Further, the lower electrode layer 40 may be in contact with the entire back surface of the substrate 10 or may be in contact with only part of the back surface of the substrate 10.

[Manufacturing Method]

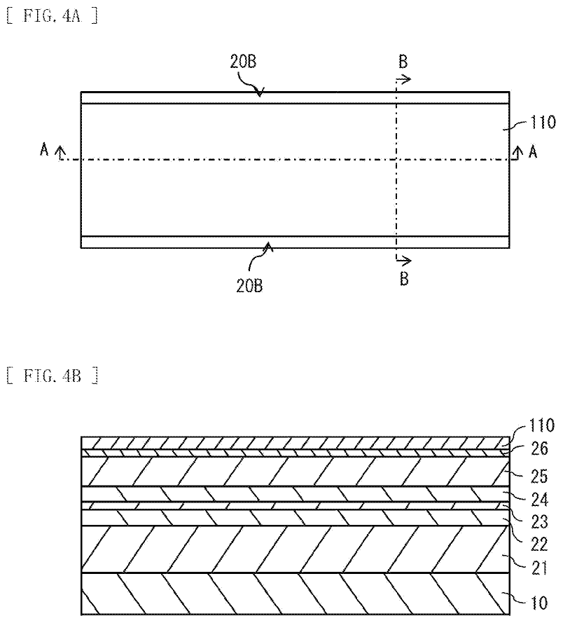

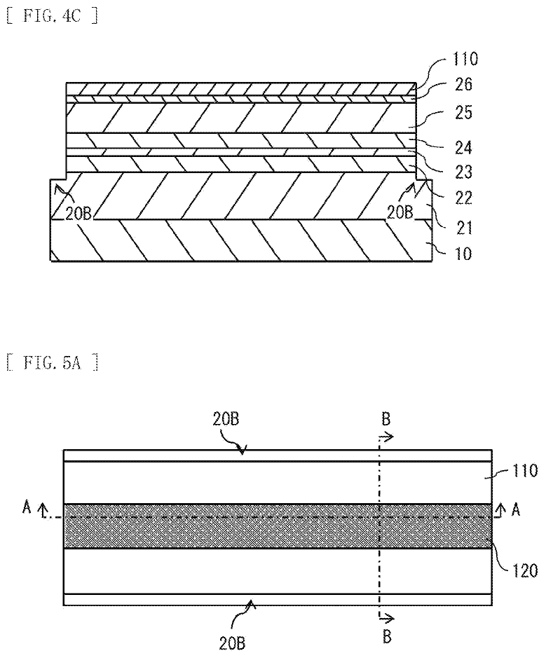

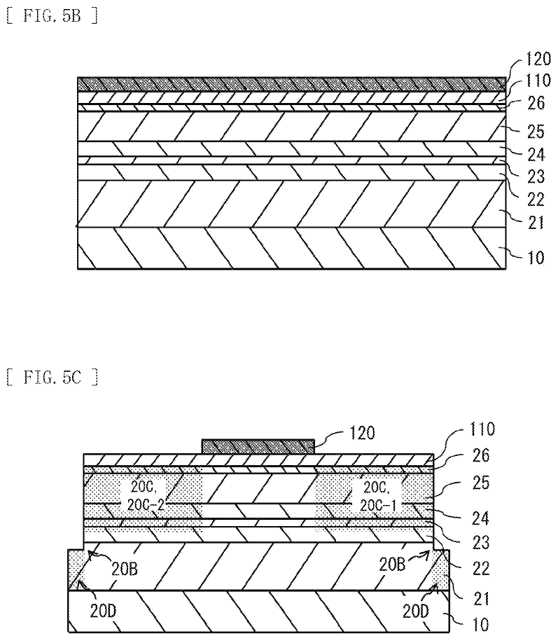

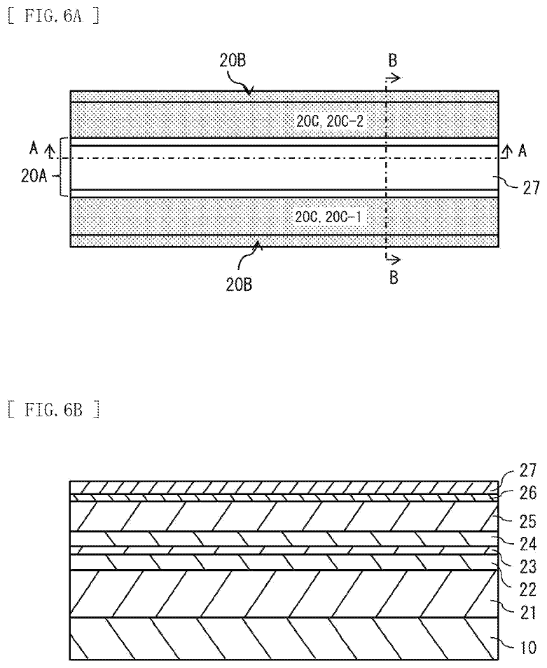

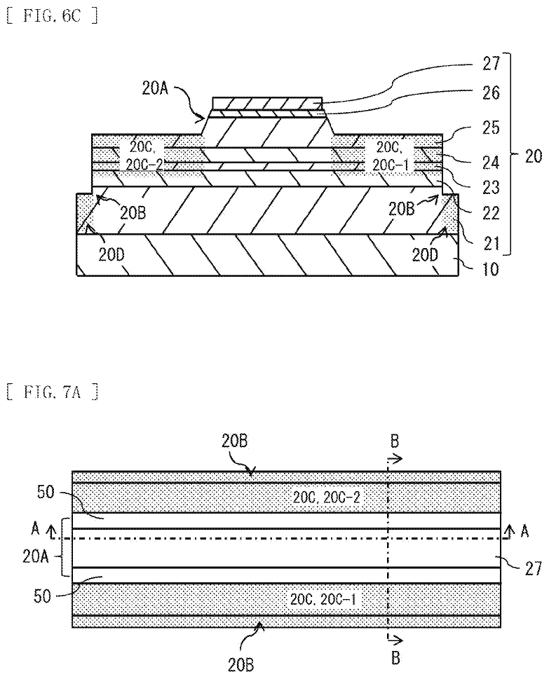

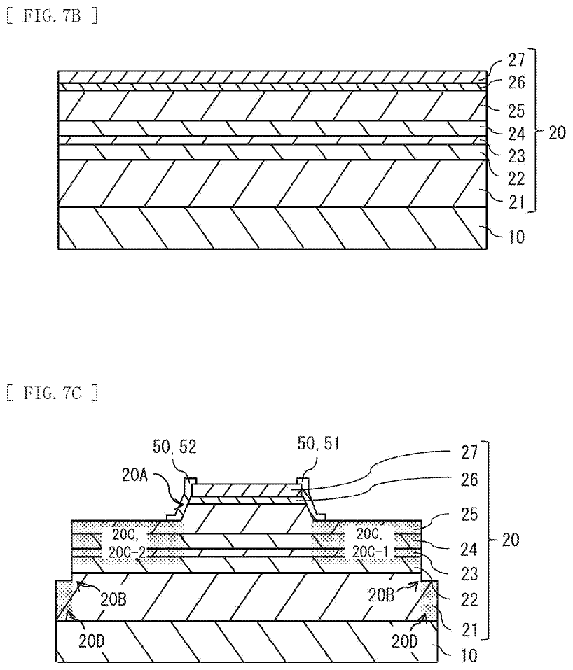

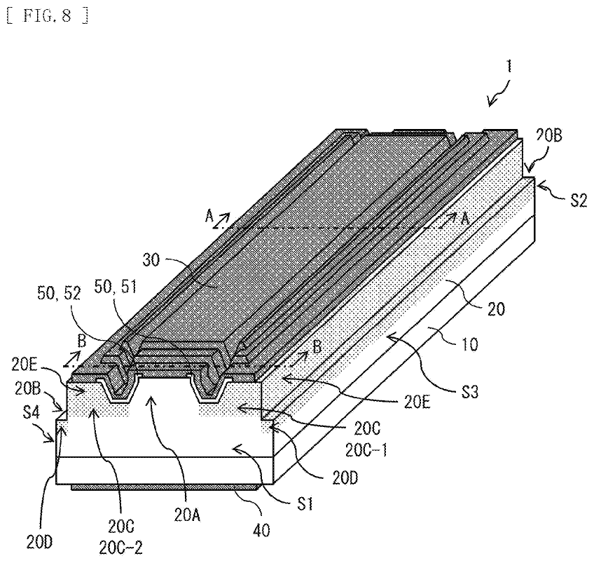

Next, a manufacturing method of the semiconductor laser 1 will be described with reference to FIGS. 4A to 7C. FIG. 4A illustrates a planar configuration example of a part of the wafer in the manufacturing process of the semiconductor laser 1. FIG. 4B illustrates a cross-sectional configuration example of FIG. 4A taken along line A-A. FIG. 4C illustrates a cross-sectional configuration example of FIG. 4A taken along line B-B. FIG. 5A illustrates an example of the manufacturing process following FIG. 4A. FIG. 5B illustrates a cross-sectional configuration example of FIG. 5A taken along line A-A. FIG. 5C illustrates a cross-sectional configuration example of FIG. 5A taken along line B-B. FIG. 6A illustrates an example of the manufacturing process following FIG. 5A. FIG. 6B illustrates a cross-sectional configuration example of FIG. 6A taken along line A-A. FIG. 6C illustrates a cross-sectional configuration example taken along line B-B of FIG. 6A. FIG. 7A illustrates an example of the manufacturing process following FIG. 6A. FIG. 7B illustrates a cross-sectional configuration example of FIG. 7A taken along line A-A. FIG. 7C illustrates a cross-sectional configuration example of FIG. 7A taken along line B-B. In FIGS. 4A, 4B, 5A, 5B, 6A, 6B, 7A, and 7B, both side surfaces correspond to locations where the wafer is to be cleaved. In FIGS. 4C, 5C, 6C and 7C, the sides correspond to where the wafer will be diced, cleaved, or cleaved.

In order to manufacture the semiconductor laser 1, a compound semiconductor is collectively formed on a substrate 10 that includes GaN by an epitaxial crystal growth method such as MOCVD (Metal Organic Chemical Vapor Deposition). At this time, as raw materials for the compound semiconductor, for example, trimethylgallium ((CH₃)₃Ga) is used as a raw material gas for gallium, trimethylaluminum ((CH₃)₃Al) is used as a raw material gas for aluminum, and for example, trimethylindium ((CH₃)₃In) is used as a raw material gas for indium. In addition, ammonia (NH₃) is used as a raw material gas for nitrogen. Further, monosilane (SiH₄), for example, is used as a raw material gas for silicon, and bis=cyclopentadienylmagnesium ((C₅H₅)₂Mg), for example, is used as a raw material gas for magnesium. As a result, the lower clad layer 21 to contact layer 26 are formed on the substrate 10.

Next, an etching mask layer 110 that includes SiO₂, SiN, or the like is formed on the contact layer 26. For example, after forming a dielectric layer that includes SiO₂, SiN, or the like by vapor deposition, sputtering, or the like, a resist layer is formed on the dielectric layer, and the resist layer is patterned by photolithography, thereby obtaining a resist layer having a predetermined pattern. Using the resist layer having the predetermined pattern as a mask, the dielectric layer is selectively etched by the RIE method using a fluorine-based gas or hydrofluoric acid-based wet etching. As a result, an etching mask layer 110 is obtained.

Next, using the etching mask layer 110 as a mask, etching is selectively performed by the RIE method using a chlorine-based gas until the active layer 23 is penetrated, thereby forming the stepped portion 20B (FIGS. 4A to 4C). Subsequently, after forming a resist layer 120 on the etching mask layer 110, ions are implanted using the resist layer 120 as a mask, and high-resistance regions 20C (20C-1, 20C-2) and 20D are formed at a location not covered with the resist layer 120 (FIGS. 5A to 5C).

Next, after removing the etching mask layer 110 and the resist layer 120, a resist layer is formed with an opening corresponding to a region where the second upper clad layer 27 is to be formed, and the second upper clad layer 27 is formed by, for example, a vacuum deposition method or a sputtering method. Subsequently, at least a part of the second upper clad layer 27, the contact layer 26, and the first upper clad layer 25 are removed by etching, for example, by RIE. As a result, the ridge 20A is formed, and the second upper clad layer 27 is formed on the ridge 20A (FIGS. 6A to 6C).

Next, after forming an insulating layer on the entire surface including the second upper clad layer 27 by using, for example, a vacuum deposition method or a sputtering method, an insulating layer 50 (51, 52) in contact with the side surface of the ridge 20A is formed by patterning using, for example, an RIE method or a solution containing hydrogen fluoride. (FIGS. 7A to 7C).

Next, after forming a metal layer for forming the pad metal 31 on the surfaces of the second upper clad layer 27, the insulating layer 50, and the foot of the ridge 20A, for example, by vacuum deposition or sputtering, for example, lift-off is performed to form the pad metal 31. At this time, the pad metal 31 is formed in a region between the resonator end faces S1 and S2 and separated from the resonator end faces S1 and S2 by a predetermined gap. Furthermore, the pad metal 31 is formed in a region between the side surfaces S3 and S4 and separated from the side surfaces S3 and S4 by a predetermined gap. The pad metal 31 may be formed using the RIE method or the milling method instead of the lift-off method.

Next, after forming a metal layer for forming the barrier metal 32 on the surface including the pad metal 31 by, for example, a vacuum deposition method or a sputtering method, the barrier metal 32 is formed by performing, for example, a lift-off method. At this time, the barrier metal 32 is formed so as to cover the pad metal 31. The barrier metal 32 may be formed using the RIE method or the milling method instead of the lift-off method.

Next, after forming a metal layer for forming the bonding metal 33 on the surface of the barrier metal 32 by, for example, vacuum deposition or sputtering, the bonding metal 33 is formed by, for example, a lift-off method. At this time, the bonding metal 33 is formed in a region between the resonator end faces S1 and S2 and separated from the resonator end faces S1 and S2 by a predetermined gap. Furthermore, the bonding metal 33 is formed in a region between the side surfaces S3 and S4 and separated from the side surfaces S3 and S4 by a predetermined gap. The bonding metal 33 may be formed using the RIE method or the milling method instead of the lift-off method.

Next, after forming a metal layer for forming the lower electrode layer 40 on the back surface of the substrate 10 by, for example, a vacuum deposition method or a sputtering method, the lower electrode layer 40 is formed by, for example, a lift-off method. Next, the substrate 10 is cut into bars, and if necessary, a coating film is formed on the exposed end faces to control the reflectance. Furthermore, the semiconductor laser 1 is produced by cutting out elements from the bar-shaped substrate 10 and forming chips.

[Operation]

In the semiconductor laser 1 configured as described above, when a predetermined voltage is applied between the upper electrode layer 30 and the lower electrode layer 40, a current is injected into the active layer 23 through the ridge 20A. Light emission occurs due to recombination of electrons and holes. This light is reflected by the pair of resonator end faces S1 and S2 and confined by the lower clad layer 21, the first upper clad layer 25, and the second upper clad layer 27, thereby causing laser oscillation at a predetermined oscillation wavelength. At this time, an optical waveguide region in which the oscillated laser light is guided is formed in the semiconductor layer 20. The optical waveguide region is formed in a region immediately below the ridge 20A with the active layer 23 at the center. Laser light having a predetermined oscillation wavelength is emitted to the outside from one resonator end face S1.

[Effects]

Next, effects of the semiconductor laser 1 will be described.

An edge-emitting semiconductor laser is demanded to have an improved heat dissipation property in order to suppress a decrease in output due to a heat generation. For example, it is conceivable to fix the semiconductor laser to a heat exhausting member such as a heat sink by junction down. The junction-down refers to a form in which the semiconductor laser is fixed to the heat exhaust member with the electrode closer to the light emitting region of the semiconductor laser facing toward the heat exhaust member. However, when the semiconductor laser is fixed to the heat-dissipating member by junction-down, an insulating layer such as SiO₂ or SiN provided to prevent an unnecessary current path from being formed between the electrode fixed to the heat-dissipating member and the light-emitting region may not provide sufficient heat dissipation.

In contrast, in the present embodiment, the insulating layer 50 is formed in contact with both side surfaces of the ridge 20A. Further, the upper electrode layer 30 is formed that is electrically coupled to the upper surface of the ridge 20A, and in contact with the exposed portion of the high-resistance region 20C which is not covered with the insulating layer 50. As a result, the heat generated in the active layer 23 is transmitted to the upper electrode layer 30 via the upper surface of the ridge 20A and the high-resistance region 20C, making it possible to increase the heat dissipation as compared with a case where an insulating layer is provided that covers a side surface or a foot of the ridge 20A. In addition, because it is difficult for a current to flow in the high-resistance region 20C, it is possible to improve heat dissipation while preventing a current path from being generated at a location other than the ridge 20A.

Further, in the present embodiment, the high-resistance region 20C is a region formed by increasing the resistance of a portion of the first upper clad layer 25 and the like by ion implantation into the first upper clad layer 25 and the like. As a result, it is possible to increase the heat dissipation as compared with a case where an insulating layer is provided to cover the side surface and the foot of the ridge 20A. In addition, because it is difficult for a current to flow in the high-resistance region 20C, it is possible to improve heat dissipation while preventing a current path from being generated at a location other than the ridge 20A.

Further, in the present embodiment, the insulating layer 51 formed on one side surface (first side surface) of the ridge 20A is formed from the first side to an edge of the high-resistance region 20C-1, and the insulating layer 52 formed on the other side surface (second side surface) of the ridge 20A is formed from the second side to an edge of the high-resistance region 20C-2. As a result, it is possible to improve heat dissipation while preventing a current path from being generated at a location other than the ridge 20A.

Moreover, in the present embodiment, the high-resistance region 20C is formed to a depth reaching the active layer 23. Thereby, it is possible to define a region into which a current is injected into the active layer 23 by the high-resistance region 20C. Furthermore, because the high-resistance region 20C has a lower refractive index than the semiconductor region surrounding the high-resistance region 20C, it is possible to achieve lateral optical confinement by the high-resistance region 20C.

Further, in the present embodiment, the high-resistance region 20C is also formed on the resonator end faces S1, S2 and the side surfaces S3, S4. As a result, for example, even if the upper electrode layer 30 protrudes from the resonator end faces S1, S2 and the side surfaces S3, S4 or touches the resonator end faces S1, S2 and the side surfaces S3, S4, the high-resistance region 20C makes it possible to prevent a current path from being generated at a location other than the ridge 20A. In addition, it is possible to prevent a current path from being generated due to a solder creeping up to a side surface. Therefore, it is possible to improve heat dissipation while preventing a current path from being generated at a location other than the ridge 20A.

### 2. Modification Examples

Next, modification examples of the semiconductor laser 1 according to the above embodiment will be described.

### Modification Example A

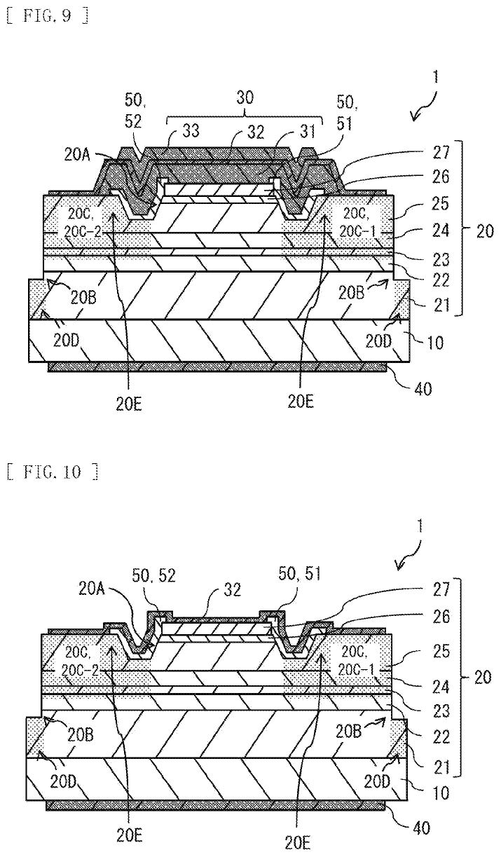

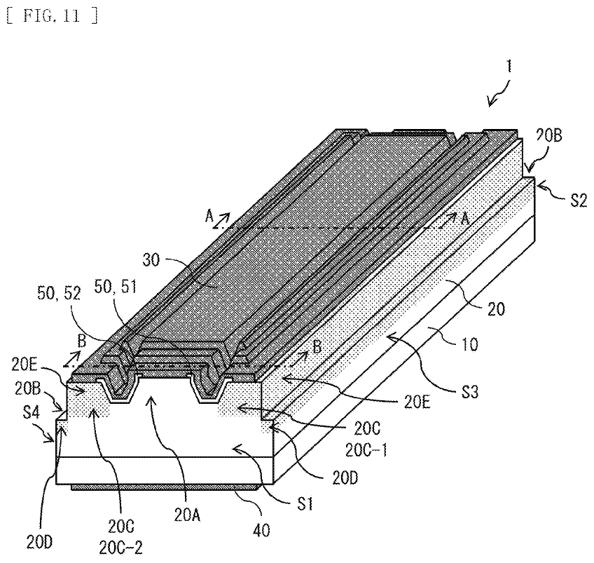

FIG. 8 illustrates a modification example of the semiconductor laser 1 according to the above embodiment. FIG. 9 illustrates an example of a cross-sectional configuration of the semiconductor laser 1 of FIG. 8 taken along line A-A. FIG. 10 illustrates an example of a cross-sectional configuration of the semiconductor laser 1 of FIG. 8 taken along line B-B.

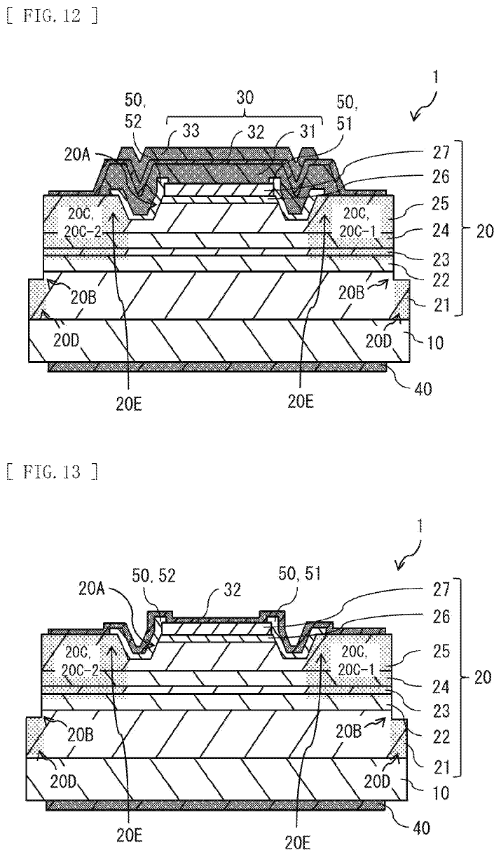

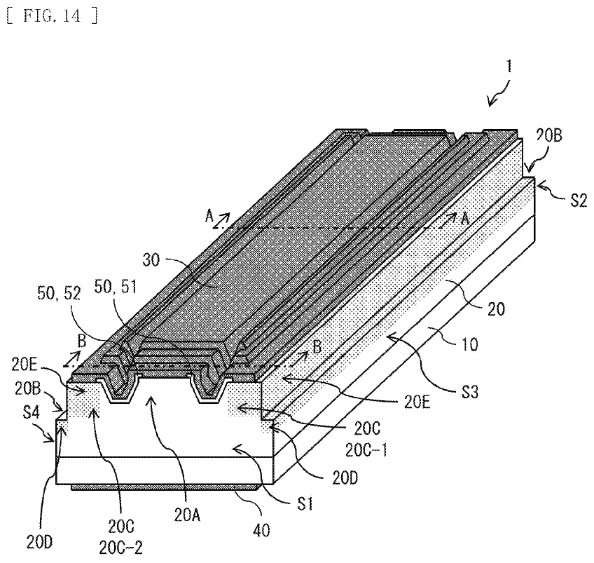

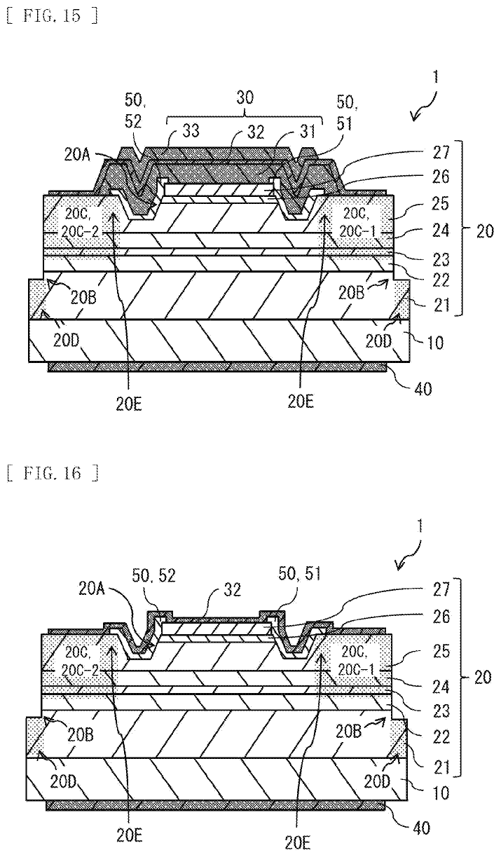

In the above embodiment, for example, as illustrated in FIGS. 8 to 10, pedestals 20E for protecting the ridge 20A may be formed on both sides of the ridge 20A (positions facing each other with the ridge 20A in between). For example, as illustrated in FIGS. 9 and 10, the pedestal 20E has a configuration in which the second upper clad layer 27 is omitted from the ridge 20A and a high-resistance region 20C is further formed in a region including the outermost surface. At this time, for example, as illustrated in FIGS. 8 to 10, the high-resistance region 20C may be formed from directly below a bottom surface of the groove, positioned between the pedestal 20E and the ridge 20A, to the pedestal 20E. It should be noted that, for example, as illustrated in FIGS. 11 to 13 and FIGS. 14 to 16, the high-resistance region 20C may be formed in a region of the foot of the ridge 20A excluding a location directly below the bottom surface of the groove, positioned between the ridge 20A and the pedestal 20E, and formed at the pedestal 20E.

Also in this modification example, the insulating layer 50 is formed from the side surface of the ridge 20A to the edge of the high-resistance region 20C, and is formed over the outermost surface of the pedestal 20E via the bottom surface of the groove from the side surface of the ridge 20A, for example. As a result, the heat generated in the active layer 23 is transferred to the upper electrode layer 30 through the groove and the pedestal 20E, so that heat dissipation is improved as compared with a case where an insulating layer is provided to cover the side surface and the foot of the ridge 20A. In addition, because it is difficult for a current to flow in the high-resistance region 20C, it is possible to improve heat dissipation while preventing a current path from being generated at a location other than the ridge 20A.

### Modification Example B

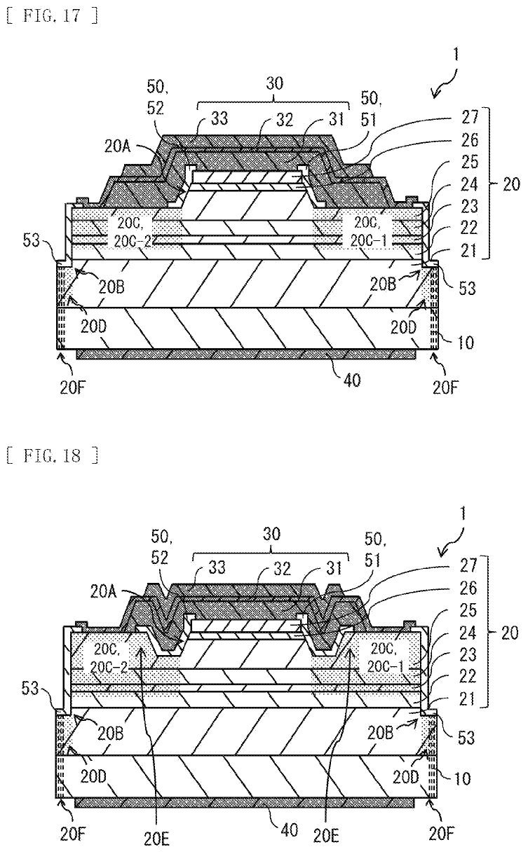

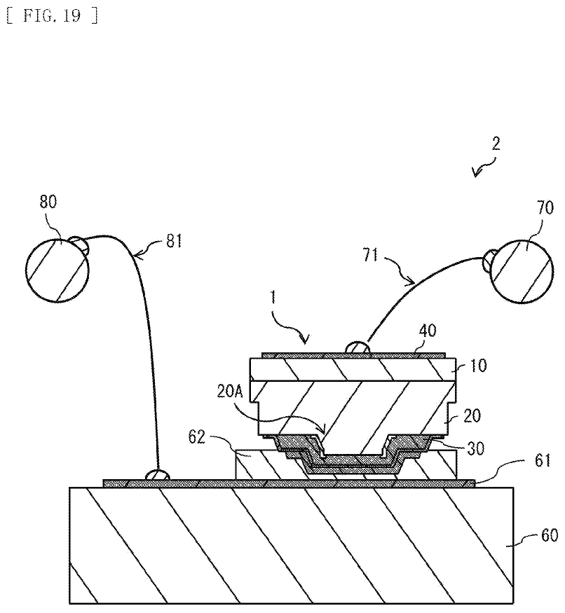

In the above embodiment and the modification examples thereof, for example, as illustrated in FIGS. 17 and 18, the semiconductor layer 20 may have a defect concentration region at the pair of side surfaces S3 and S4 and in the vicinity thereof. The defect concentration regions 20F are so formed at the semiconductor layer 20 as to correspond to the defect concentration region of the GaN substrate, for example, by forming the semiconductor layer 20 on the GaN substrate by crystal growth when the substrate 10 is configured by a GaN substrate including the defect concentration region. In a case where the defect concentrated region 20F is formed in the stepped portion 20B, the high-resistance region 20D is formed in the stepped portion 20B including the defect concentrated region 20F, and the insulating layer 53 may be so formed as to cover a location exposed to the stepped portion 20B (hereinafter referred to as “defect exposed portion”.) of the defect concentrated region 20F. Further, the insulating layer 53 may be formed so as to cover the surface of the semiconductor layer 20 which is exposed between the defect exposed portion and the end of the upper electrode layer 30. At this time, the end of the insulating layer 53 may be provided between the end of the upper electrode layer 30 and the upper surface of the semiconductor layer 20. The insulating layer 53 includes, for example, the same material as the insulating layer 50 described above. As a result, for example, even if the upper electrode layer 30 protrudes to the side surfaces S3 and S4 for some reason, the insulating layer 53 prevents an electrical short circuit between the upper electrode layer 30 and the defect concentration region 20F. In addition, it is also possible to prevent a current path from being generated due to a solder creeping up to the side surface.

### Modification Example C

In the above embodiment and the modification examples thereof, the lower electrode layer 40 is in contact with the back surface of the substrate 10. However, in the above embodiment and the modification examples thereof, the surface of the lower clad layer 21 or the lower guide layer 22 on the upper electrode layer 30 side may be exposed, and the lower electrode layer 40 may be brought into contact with the exposed surface. In this case, it is possible to make all electrical connections with the semiconductor laser 1 only on one side of the substrate 10.

### Modification Example D

In the above embodiment and the modification example thereof, one ridge 20A is provided, but a plurality of the ridges 20A may be provided. In this case, for example, by providing the high-resistance region 20C in the region sandwiching the plurality of ridges 20A, it is possible to improve heat dissipation.

### Modification Example E

In the above embodiment and the modification examples thereof, the semiconductor laser 1 may include a material different from the GaN-based material (for example, a GaAs-based material). Even in this case, it is possible to achieve effects similar to those of the above-described embodiment and the modification examples.

### 3. Second Embodiment

[Configuration]

A semiconductor laser device 2 according to a second embodiment of the present disclosure will be described. FIG. 19 illustrates a cross-sectional configuration example of the semiconductor laser device 2 according to the present embodiment.

The semiconductor laser device 2 includes a semiconductor laser 1 provided with a ridge 20A, a submount 60, and leads 70, 70. In the present embodiment, the semiconductor laser 1 is mounted on the upper surface of the submount 60 with the surface on which the ridge 20A is formed facing the submount 60 side. That is, the semiconductor laser 1 is mounted on the upper surface of the submount 60 with the junction down. A connection pad 61 is provided on the upper surface of the submount 60.

The upper electrode layer 30 (specifically, the bonding metal 33) of the semiconductor laser 1 is electrically coupled to the connection pad 61 of the submount 60 via a solder 62. The bonding metal 33 is in contact with the solder 62. The connection pad 61 is electrically coupled to a lead 80 via a bonding wire 81. A lower electrode layer 40 of the semiconductor laser 1 is electrically coupled to a lead 70 via a bonding wire 71. The bonding wire 81 is coupled to the connection pad 61 and the lead 80 by, for example, making the end of the bonding wire 81 ball-shaped and applying ultrasonic waves and heat to the ball-shaped end. The bonding wire 71 is coupled to the lower electrode layer 40 and the lead 70 by, for example, making the end of the bonding wire 71 ball-shaped and applying ultrasonic waves and heat to the ball-shaped end. The solder 62 includes, for example, a Sn-based solder material.

In the present embodiment, as with the above-described embodiments, in the semiconductor laser 1, it is possible to prevent a current path from being generated at a location other than the ridge 20A while enhancing heat dissipation. As a result, it is possible to rapidly discharge the heat generated by the semiconductor laser 1 to the submount 60 via the upper electrode layer 30, the solder 62, and the connection pad 61, making it possible to increase the output of the semiconductor laser 1.

Although the present disclosure has been described with reference to the embodiments and the modification examples, the present disclosure is not limited to the above-described embodiments and the like, and various modifications are possible. It should be noted that the effects described in this specification are merely examples. The effects of the present disclosure are not limited to the effects described herein. The disclosure may have effects other than those described herein.

Further, for example, the present disclosure may have the following configurations.

(1)

A Semiconductor Laser Including:
a first semiconductor layer;
an active layer;
a second semiconductor layer stacked on the first semiconductor layer with the active layer interposed therebetween, and having a strip-shaped ridge, and a high-resistance region at a foot of the ridge;
an insulating layer formed so as to be in contact with both side surfaces of the ridge in a width direction of the ridge and to expose at least a portion of the high-resistance region; and
an electrode layer electrically coupled to an upper surface of the ridge, and in contact with an exposed portion of the high-resistance region which is not covered with the insulating layer.
   (2)

The semiconductor laser according to (1), in which the high-resistance region is a region formed by increasing a resistance of a portion of the second semiconductor layer by ion implantation into the second semiconductor layer.

(3)

The Semiconductor Laser According to (1) or (2), in which
the insulating layer has a first insulating layer and a second insulating layer facing each other with the upper surface of the ridge therebetween and extending in a direction parallel to an extending direction of the ridge,
the high-resistance region includes a first high-resistance region formed on a first side surface side that is one side surface of the ridge, and a second high-resistance region formed on a second side surface side that is the other side surface of the ridge,
the first insulating layer is formed from the first side surface to an edge of the first high-resistance region,
the second insulating layer is formed from the second side surface to an edge of the second high-resistance region, and
the electrode layer is in contact with an exposed portion of the upper surface of the ridge which is not covered with the first insulating layer and the second insulating layer, and is in contact with the first high-resistance layer and the second high-resistance layer.
   (4)

The semiconductor laser according to any one of (1) to (3), in which the high-resistance region is formed to a depth reaching the active layer.

(5)

The semiconductor laser according to any one of (1) to (4), in which
the semiconductor layer including the first semiconductor layer, the active layer, and the second semiconductor layer further has a pair of resonator end faces facing each other with the ridge in between in a direction parallel to an extending direction of the ridge, and a pair of end faces facing each other in a direction parallel to the width direction of the ridge, and
the high-resistance region is also formed at the pair of resonator end faces and the pair of end faces.
   (6)

The semiconductor laser according to (5), in which
the semiconductor layer has a defect concentration region at and in the vicinity of the pair of end faces, and
the high-resistance region is also formed at the defect concentration region.
   (7)

The semiconductor laser according to any one of (1) to (6), in which
the second semiconductor layer has a pedestal at positions facing each other with the ridge in between, and
the high-resistance region is formed from directly below a bottom surface of a groove, positioned between the ridge and the pedestal, to the pedestal.
   (8)

The semiconductor laser according to any one of (1) to (6), in which
the second semiconductor layer has a pedestal at positions facing each other with the ridge in between, and
the high-resistance region is formed in a region of the foot of the ridge excluding a location directly below a bottom surface of a groove, positioned between the ridge and the pedestal, and formed at the pedestal.
   (9)

A semiconductor laser device including:
a semiconductor laser; and
a connection pad electrically coupled to the semiconductor laser,
the semiconductor laser including
a first semiconductor layer,
an active layer,
a second semiconductor layer stacked on the first semiconductor layer with the active layer interposed therebetween, and having a strip-shaped ridge, and a high-resistance region at a foot of the ridge,
an insulating layer formed so as to be in contact with both side surfaces of the ridge in a width direction of the ridge and to expose at least a portion of the high-resistance region, and
an electrode layer electrically coupled to an upper surface of the ridge and the connection pad, and in contact with an exposed portion of the high-resistance region which is not covered with the insulating layer.

In the semiconductor laser and the semiconductor laser device according to one embodiment of the present disclosure, the insulating layer is formed in contact with the both side surfaces of the ridge, and the electrode layer is formed that is electrically coupled to the upper surface of the ridge, and in contact with the exposed portion of the high-resistance region which is not covered with the insulating layer. As a result, a heat generated in the active layer is transferred to the electrode layer through the upper surface of the ridge and the high-resistance region, making it possible to improve a heat dissipation as compared with a case where an insulating layer is provided to cover a side surface and a foot of the ridge. In addition, because it is difficult for a current to flow in the high-resistance region, it is possible to improve heat dissipation while preventing a current path from being generated at a location other than the ridge. Note that the effects of the present disclosure are not necessarily limited to the effects described herein, and may be any of the effects described herein.

The present application claims the benefit of Japanese Priority Patent Application JP2020-150096 filed with the Japan Patent Office on Sep. 7, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor laser comprising:
a first semiconductor layer;
an active layer;
a second semiconductor layer stacked on the first semiconductor layer with the active layer interposed therebetween, and having a strip-shaped ridge, and a high-resistance region at a foot of the ridge;
an insulating layer formed so as to be in contact with both side surfaces of the ridge in a width direction of the ridge and to expose at least a portion of the high-resistance region; and
an electrode layer electrically coupled to an upper surface of the ridge, and in contact with an exposed portion of the high-resistance region which is not covered with the insulating layer.

2. The semiconductor laser according to claim 1, wherein the high-resistance region is a region formed by increasing a resistance of a portion of the second semiconductor layer by ion implantation into the second semiconductor layer.

3. The semiconductor laser according to claim 1, wherein
the insulating layer has a first insulating layer and a second insulating layer facing each other with the upper surface of the ridge therebetween and extending in a direction parallel to an extending direction of the ridge,
the high-resistance region includes a first high-resistance region formed on a first side surface side that is one side surface of the ridge, and a second high-resistance region formed on a second side surface side that is the other side surface of the ridge,
the first insulating layer is formed from the first side surface to an edge of the first high-resistance region,
the second insulating layer is formed from the second side surface to an edge of the second high-resistance region, and
the electrode layer is in contact with an exposed portion of the upper surface of the ridge which is not covered with the first insulating layer and the second insulating layer, and is in contact with the first high-resistance layer and the second high-resistance layer.

4. The semiconductor laser according to claim 1, wherein the high-resistance region is formed to a depth reaching the active layer.

5. The semiconductor laser according to claim 1, wherein
the semiconductor layer including the first semiconductor layer, the active layer, and the second semiconductor layer further has a pair of resonator end faces facing each other with the ridge in between in a direction parallel to an extending direction of the ridge, and a pair of end faces facing each other in a direction parallel to the width direction of the ridge, and
the high-resistance region is also formed at the pair of resonator end faces and the pair of end faces.

6. The semiconductor laser according to claim 5, wherein
the semiconductor layer has a defect concentration region at and in vicinity of the pair of end faces, and
the high-resistance region is also formed at the defect concentration region.

7. The semiconductor laser according to claim 1, wherein
the second semiconductor layer has a pedestal at positions facing each other with the ridge in between, and
the high-resistance region is formed from directly below a bottom surface of a groove, positioned between the ridge and the pedestal, to the pedestal.

8. The semiconductor laser according to claim 1, wherein
the second semiconductor layer has a pedestal at positions facing each other with the ridge in between, and
the high-resistance region is formed in a region of the foot of the ridge excluding a location directly below a bottom surface of a groove, positioned between the ridge and the pedestal, and formed at the pedestal.

9. A semiconductor laser device comprising:
a semiconductor laser; and
a connection pad electrically coupled to the semiconductor laser,
the semiconductor laser including
a first semiconductor layer,
an active layer,
a second semiconductor layer stacked on the first semiconductor layer with the active layer interposed therebetween, and having a strip-shaped ridge, and a high-resistance region at a foot of the ridge,
an insulating layer formed so as to be in contact with both side surfaces of the ridge in a width direction of the ridge and to expose at least a portion of the high-resistance region, and
an electrode layer electrically coupled to an upper surface of the ridge and the connection pad, and in contact with an exposed portion of the high-resistance region which is not covered with the insulating layer.
